(19) United States
(12) Patent Application Publication
(10) Pub. No.: US 2022/0084845 A1
(43) Pub. Date: Mar. 17, 2022

(54) HIGH CONDUCTANCE PROCESS KIT

(71) Applicant: Applied Materials, Inc., Santa Clara, CA (US)

(72) Inventors: Samartha Subramanya, Karnataka (IN); Dmitry Lubomirsky, Cupertino, CA (US); Mehmet Tugrul Samir, Mountain View, CA (US); Lala Zhu, Fremont, CA (US); Martin Y. Choy, San Ramon, CA (US); Son T. Nguyen, San Jose, CA (US); Pranav Gopal, Alameda, CA (US)

(73) Assignee: Applied Materials, Inc., Santa Clara, CA (US)

(21) Appl. No.: 17/023,987

(22) Filed: Sep. 17, 2020

(51) Int. Cl. H01L 21/67; B05B 1/18; C23C 16/455; H01L 21/3065; H01J 37/305

(52) U.S. Cl. CPC H01L 21/67069; B05B 1/185; H01J 37/3053; H01L 21/30655; H01L 21/6719; C23C 16/455

(57) ABSTRACT

Exemplary semiconductor processing chambers may include showerhead. The chambers may include a pedestal configured to support a semiconductor substrate, where the showerhead and pedestal at least partially define a processing region within the semiconductor chamber. The chamber may include a spacer characterized by a first surface in contact with the showerhead and a second surface opposite the first surface. The chamber may include a pumping liner characterized by a first surface in contact with the spacer and a second surface opposite the first surface. The pumping liner may define a plurality of apertures within the first surface of the pumping liner.

### TECHNICAL FIELD

The present technology relates to semiconductor processes and equipment. More specifically, the present technology relates to chamber lid stack components and configurations.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Removal of the materials from the substrate generates particles within the processing chamber that must be removed to avoid byproduct buildup on surfaces of the processing chamber and the pedestal. Turbulent flow within the processing chamber can create additional byproduct buildup. Buildup on the underside of the platen surface of the pedestal may impact the substrate temperature and lead to non-uniformity of the patterned material layers on the substrate.

Thus, there is a need for improved systems and methods that can be used to produce high quality devices and structures. These and other needs are addressed by the present technology.

### SUMMARY

Exemplary semiconductor processing chambers may include a showerhead and a pedestal configured to support a semiconductor substrate, where the showerhead and pedestal at least partially define a processing region within the semiconductor processing chamber. The semiconductor processing chamber may also include a spacer characterized by a first surface in contact with the showerhead and a second surface opposite the first surface. The semiconductor processing chamber may also include a pumping liner characterized by a first surface in contact with the spacer and a second surface opposite the first surface, where the pumping liner defines a plurality of apertures within the first surface of the pumping liner.

In some embodiments, the spacer includes an annulus, and an inner annular sidewall of the spacer extending between the first surface of the spacer and the second surface of the spacer at least partially defines the processing region. The inner annular sidewall of the spacer may be at least partially characterized by an arcuate profile extending away from the processing region in a direction towards the second surface of the spacer. The inner annular sidewall of the spacer at the second surface of the spacer may be positioned radially outward of the plurality of apertures within the first surface of the pumping liner. The second surface of the spacer may be seated on the pumping liner. The pumping liner may include an annulus characterized by an inner annular sidewall and an outer annular sidewall, and the pumping liner may define a plenum between the inner annular sidewall and the outer annular sidewall. The plurality of apertures may provide fluid access to the plenum from the first surface of the pumping liner. The inner annular sidewall of the pumping liner may extend vertically to define a rim protruding from the first surface of the pumping liner at the inner annular sidewall. The pedestal may be vertically translatable within the processing region of the semiconductor processing chamber, and the pedestal may include a platen and a stem extending from a backside of the platen. When the pedestal is in a raised operational position proximate the showerhead, a plane across the backside of the platen is maintained below an upper surface of the rim protruding from the first surface of the pumping liner.

Some embodiments of the present technology may encompass semiconductor processing systems. The systems may include a semiconductor processing chamber pumping liner. The pumping liner may include an annular member characterized by a first surface, where a plurality of apertures are defined through the first surface of the annular member. The pumping liner may also include a second surface opposite the first surface. The pumping liner may also include an inner annular sidewall and an outer annular sidewall.

In some embodiments, the second surface of the pumping liner defines a plenum about the annular member extending towards the first surface between the inner annular sidewall and the outer annular sidewall. The plurality of apertures may provide fluid access to the plenum through the first surface of the annular member. The inner annular sidewall of the annular member may extend vertically to define a rim protruding from the first surface at the inner annular sidewall. The rim may extend continuously about the inner annular sidewall.

Some embodiments of the present technology may encompass methods performed by semiconductor processing systems. The method may include flowing an etchant precursor into a remote plasma region of a semiconductor processing chamber. Plasma effluents may be generated of the etchant precursor within the remote plasma region of the semiconductor processing chamber. The plasma effluents of the etchant precursor may be flowed through a showerhead into a processing region of the semiconductor processing chamber. The plasma effluents may contact a substrate seated on a pedestal. The etch byproducts may be discharged from the processing region through a pumping liner characterized by a first surface facing the showerhead and a second surface opposite the first surface, where the pumping liner defines a plurality of apertures within the first surface of the pumping liner.

In some embodiments, the semiconductor processing chamber further includes a spacer characterized by a first surface in contact with the showerhead and a second surface opposite the first surface and in contact with the pumping liner, where the spacer includes an annulus, and where an inner annular sidewall of the spacer extending between the first surface of the spacer and the second surface of the spacer at least partially defines the processing region. The inner annular sidewall of the spacer may be at least partially characterized by an arcuate profile extending away from the processing region in a direction towards the second surface of the spacer. The inner annular sidewall of the spacer at the second surface of the spacer may be positioned radially outward of the plurality of apertures within the first surface of the pumping liner. The pumping liner may be further characterized by an inner annular sidewall, and the inner annular sidewall may extend vertically to define a rim protruding from the first surface of the pumping liner at the inner annular sidewall.

Such technology may provide numerous benefits over conventional systems and techniques. For example, embodiments of the present technology may reduce buildup of byproducts on the underside of the platen within the processing chamber and may provide more laminar flow patterns of gases and byproducts in the processing chamber. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2A shows a schematic cross-sectional view of an exemplary processing chamber according to some embodiments of the present technology.

FIG. 2B shows a schematic detailed view of a portion of the processing chamber illustrated in FIG. 2A according to some embodiments of the present technology.

FIG. 3 shows a schematic bottom view of an exemplary showerhead according to some embodiments of the present technology.

FIG. 4 illustrates a schematic cross-sectional view of an exemplary processing chamber according to some embodiments of the present technology.

FIG. 5 illustrates a perspective view of an exemplary pumping liner according to some embodiments of the present technology.

FIG. 6 illustrates an exemplary flowchart of a method for performing semiconductor etching processes according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Semiconductor processing often includes formation and removal operations for many masking and intermediate formation layers. As masking materials are increasingly used with multiple materials, improved etch selectivity may be provided utilizing modified characteristics of the films as well as adjustments to the etch processes. For example, some exemplary silicon or carbon mask films may be characterized by increased concentrations of additive materials such as boron, which may improve etch selectivity to a number of materials. Additionally, film thickness of the mask film may be increased to several hundred nanometers or more to accommodate a variety of material selectivities.

During etching, annealing, and other processes, purge gas may be flowed into the semiconductor processing chamber to exhaust byproducts of the processes from the chamber. The flow path of the purge gas can create turbulence in the semiconductor processing chamber that may result in byproducts depositing on the pedestal and other surfaces within the chamber. Buildup of byproducts within the chamber may result in temperature non-uniformity on the substrate. For example, buildup on the underside of the platen of the pedestal may impact the thermal properties for areas of the substrate that are opposite to the buildup on the underside of the platen.

Flow non-uniformity may be mitigated by optimizing parameters such as process gas flow rates, distances between components within the processing chamber, and so forth. Thermal non-uniformity can be mitigated utilizing a pedestal with heating zones to compensate for local non-uniformity. Cleaning processes that heat the chamber components beyond the sublimation temperature of the byproducts can be used to remove buildup. These mechanisms may partially compensate for the underlying problem of turbulence and byproduct buildup within the chamber, but do not address the underlying cause.

The present technology overcomes these issues by utilizing chamber components and configurations to create flow paths that do not generate turbulence and the associated buildup of byproducts. By adjusting flow pathways and component profiles, turbulence is limited and byproduct re-condensation can be controlled or limited. This may afford increased removal rates over conventional technologies, while providing chamber components and designs for improved operation and increased substrate uniformity.

Although the remaining disclosure will routinely identify specific etching processes and components incorporated in etching chambers utilizing the disclosed technology, it will be readily understood that the systems and methods are equally applicable to deposition and cleaning processes as may occur in the described chambers. Additionally, any of the components discussed may be incorporated in other chambers that may benefit from the described technology. Accordingly, the present technology should not be considered to be so limited as for use with etching processes or chambers alone. Moreover, although an exemplary chamber is described to provide foundation for the present technology, it is to be understood that the present technology can be applied with any number of semiconductor processing chambers and materials to be removed.

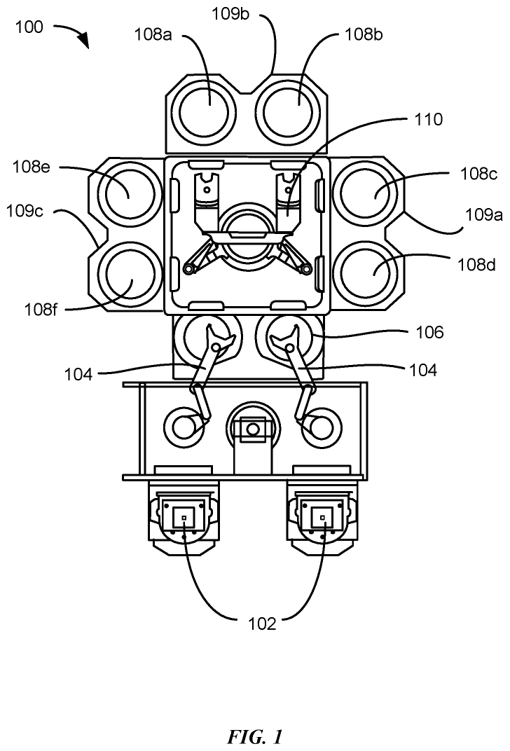

FIG. 1 shows a top plan view of one embodiment of a processing system 100 of deposition, etching, baking, and curing chambers according to embodiments, and may illustrate a foundation configured to support chambers and components according to embodiments of the present technology. As illustrated in the figure, a pair of front opening unified pods 102 may supply substrates of a variety of sizes that may be received by robotic arms 104 and placed into a low pressure holding area 106 before being placed into one of the substrate processing chambers 108a-f, positioned in tandem sections 109a-c. A second robotic arm 110 may be used to transport the substrates from the holding area 106 to the substrate processing chambers 108a-f and back. Each substrate processing chamber 108a-f, can be outfitted to perform a number of substrate processing operations including removal processes described throughout the present technology in addition to cyclical layer deposition, atomic layer deposition, chemical vapor deposition, physical vapor deposition, etch, pre-clean, degas, orientation, and other substrate processes.

The substrate processing chambers 108a-f may include one or more system components for depositing, annealing, curing and/or etching a dielectric film on the substrate. In one configuration, two pairs of the processing chambers, such as 108c-d and 108e-f, may be used to deposit dielectric material on the substrate, and the third pair of processing chambers, such as 108a-b, may be used to etch the deposited dielectric. In another configuration, all three pairs of chambers may be configured to etch a dielectric film on the substrate. Any one or more of the processes described may be carried out in one or more chambers separated from the fabrication system shown in different embodiments. It will be appreciated that additional configurations of deposition, etching, annealing, and curing chambers for dielectric films are contemplated by system 100.

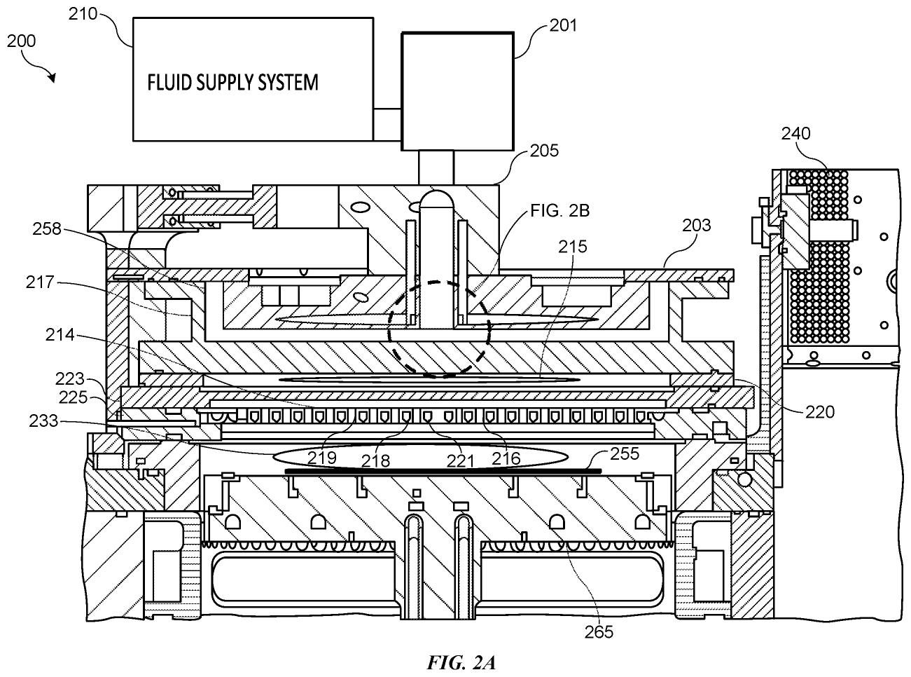

FIG. 2A shows a cross-sectional view of an exemplary process chamber system 200 with partitioned plasma generation regions within the processing chamber, and which may be configured to perform processes as described further below. System 200 may be one half of a tandem chamber operable with the platform described above. System 200 is intended to provide an overview of some of the detailed systems described throughout the present disclosure, and which may include some or all of the components and chamber configurations described throughout the present disclosure. During film etching, such as dielectric etching, metal etching, mask etching, or other removal processes, a process gas may be flowed into the first plasma region 215 through a gas inlet assembly 205. A remote plasma source unit 201 may optionally be included in the system, and may process a first gas which then travels through gas inlet assembly 205. The inlet assembly 205 may include two or more distinct gas supply channels where the second channel may bypass the remote plasma source unit 201, if included.

A gasbox 203, faceplate 217, ion suppressor 223, showerhead 225, and a substrate support or pedestal 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platen of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the remote plasma source unit 201, may pass through a plurality of holes 259, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which may allow an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively-coupled plasma to be formed in the first plasma region. A baffle (not shown) may additionally be located in the first plasma region 215, or otherwise coupled with gas inlet assembly 205, to affect the flow of fluid into the region through gas inlet assembly 205. In some embodiments, additional plasma sources may be utilized including inductively-coupled plasma sources extending about the chamber or in fluid communication with the chamber, as well as additional plasma-generating systems.

The ion suppressor 223, which may be an electrode of the capacitively-coupled remote plasma region as will be described further below, may include a plate or other geometry that defines a plurality of apertures throughout the structure, which are configured to suppress the migration of ionically-charged species out of the first plasma region 215 while allowing uncharged neutral or radical species to pass through the ion suppressor 223 into an activated gas delivery region between the suppressor and the showerhead. In some embodiments, the ion suppressor 223 may be or include a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying substrate, which in turn may increase control of the deposition and/or etch characteristics of the gas mixture. For example, adjustments in the ion concentration of the gas mixture can significantly alter its etch selectivity, such as SiNx:SiOx etch ratios, Si:SiOx etch ratios, or any other etch rates between two exposed materials. In some embodiments in which deposition is performed, the ion concentration can also shift the balance of conformal-to-flowable style depositions for dielectric materials.

The plurality of apertures in the ion suppressor 223 may be configured to control the passage of the activated gas, which may include the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the first plasma region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically-charged species traveling from the plasma generation region to the substrate. Uncharged neutral and radical species may still pass through the openings in the ion suppressor to react with the substrate. It should be noted that the complete elimination of ionically-charged species in the reaction region surrounding the substrate may not be performed in embodiments. In certain operations, ionic species may be intended to reach the substrate in order to perform the etch and/or deposition process. In these processes, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215, which may be an internal remote plasma region, into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in first plasma region 215 above showerhead 225 or substrate processing region 233 below showerhead 225. Plasma may be present in first plasma region 215 to produce the radical precursors from an inflow of, for example, a fluorine-containing precursor or other precursor. An AC voltage typically in the radio frequency (“RF”) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, gasbox 203, and gas inlet assembly 205 may intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

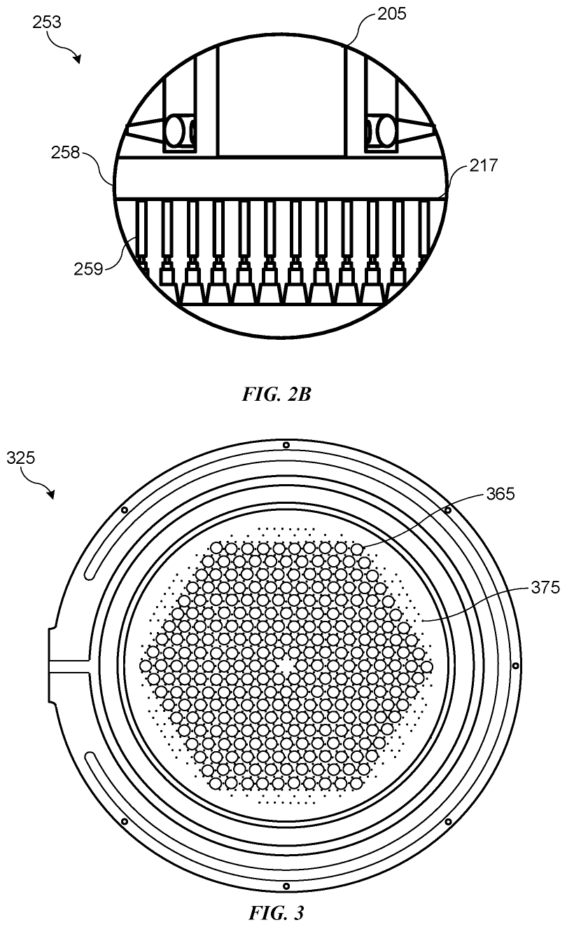

The gas distribution assemblies such as showerhead 225 for use in the processing chamber system 200 may be referred to as dual-channel showerheads and are additionally detailed in the embodiments described in FIG. 3. The dual-channel showerhead may facilitate etching processes that allow for separation of etchants outside of the processing region 233 to provide limited interaction with chamber components and each other prior to being delivered into the processing region.

The showerhead 225 may include an upper plate 214 and a lower plate 216 as illustrated in FIG. 1. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly or showerhead 225.

FIG. 3 is a bottom view of a showerhead 325 for use with a processing chamber according to some embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

As previously described, the present technology may include any number of modifications to a chamber, such as illustrated in system 200, in order to perform semiconductor processing. While some conventional configurations may include a spacer and pumping liner, they do not include an arcuate profile of the inner annular surface of the spacer, and they do not include a rim or apertures on the surface of the pumping liner facing the showerhead. Accordingly, many of these conventional designs may necessarily produce byproduct buildup on the underside of the platen and turbulent flow across the surface of the wafer, as will be described further below. The remaining disclosure will describe a variety of chamber components and configurations that may be included in a number of combinations with one or more components of system 200 described above. By including one or more modified components within system 200, byproduct buildup may be limited and laminar flow within the processing chamber improved.

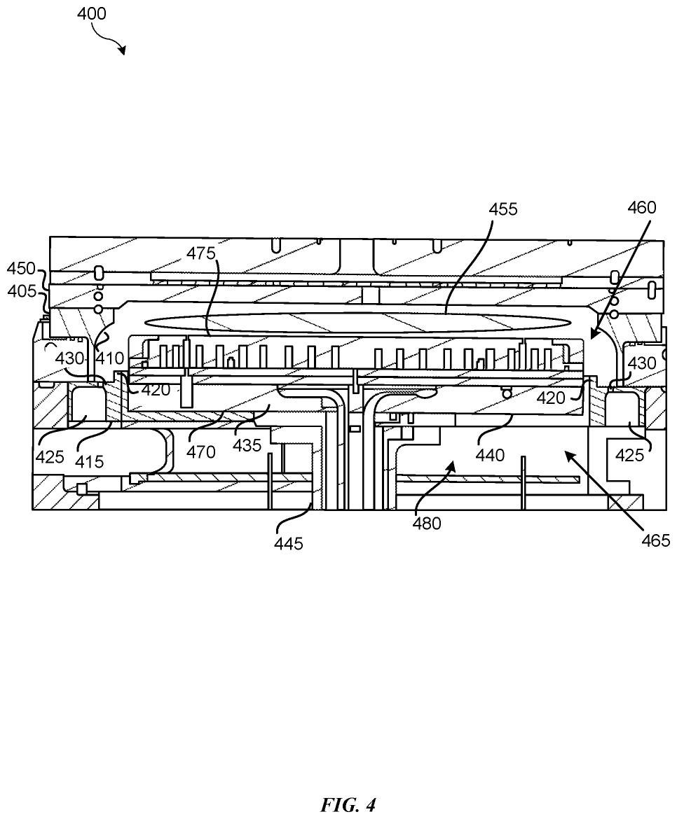

FIG. 4 illustrates a cross-sectional view of an exemplary processing chamber system 400 having configuration implementations for improving laminar flow and reducing byproduct buildup. The processing chamber system 400 may correspond with processing chamber system 200 of FIG. 2A, and may include any of the components or configurations described above. The processing chamber system 400 may be used for semiconductor production processes including etching, annealing, deposition, among any other semiconductor processing.

The processing chamber 400 includes a spacer 405. The spacer 405 is disposed between and in contact with the showerhead 450 and the pumping liner 415. The spacer 405 may be annular, such that an inner surface 410 of the spacer 405 may define a portion of the processing region 455. The inner surface 410 of the spacer 405 may be curved to form a void area into which the processing region 455 may extend to define an exterior flow path radially outward of substrate. This void area may improve the flow path 460 of gases and byproducts being exhausted from the processing region 455. Stated differently, the inner annular surface 410 of the spacer 405 may at least partially have an arcuate profile extending away from the processing region 455 in a direction towards the pumping liner 415, as shown. Conventional spacer and component configurations may include notches and corners that may produce eddies of flowing materials, which may increase residence time of byproduct materials in the chamber, and may increase the opportunity for detrimental re-deposition on cooled exterior surfaces within the chamber. These particles may then fall off during wafer transfer or subsequent processing, which may cause defects on processed substrates, and potentially device failure. By forming flow path 460 utilizing arcuate chamber features, removal of materials may be removed by limiting interaction with component features. The flow may also improve uniformity of the process being performed as the configuration encourages laminar flow of process gases across the wafer, which may improve operations by providing more uniform residence time of materials in contact with the substrate.

The processing chamber 400 may include a pumping liner 415. The pumping liner 415 may include a rim 420 that extends upward along the inner surface of the pumping liner 415. The pumping liner 415 may be annular and have a hollow structure such that a plenum 425 is defined between the surfaces of the pumping liner 415. The pumping liner 415 defines apertures 430 that provide fluid access to the plenum 425. While conventional pumping liners may provide access to the pumping plenum through a sidewall of the pumping liner, by incorporating the apertures in a surface facing the spacer and overlying components, the flow path may be maintained and not produce flow direction changes, which may increase the likelihood of re-deposition within the chamber. The apertures 430 are disposed within the surface of the pumping liner 415 facing the showerhead 450. Gases and byproducts may be exhausted from the processing region 455 through the apertures 430 into the plenum 425. The pumping liner may be fluidly coupled with a system foreline, which may be coupled with a pumping system. The pumping system may be configured to draw the gases and byproducts from the processing region 455 through the apertures 430 in the plenum 425 and out of the processing chamber system 400. The spacer 405 may be seated on the pumping liner 415 such that the inner annular surface 410 of the spacer 405 is radially outward of the apertures 430 of the pumping liner 415. As such, the processing region 455 that extends into the void area created by the arcuate profile of the inner surface 410 of the spacer 405 can fluidly access the plenum 425 via the apertures 430.

The processing chamber 400 may include a showerhead 450, which may correspond with showerhead 225 of FIG. 2A and/or showerhead 325 of FIG. 3. Gases may be flowed from an overlying gasbox to form a plasma in a plasma region as previously described. The plasma effluents may enter the processing region 455 through apertures in the showerhead 450. The processing region 455 may correspond with processing region 233 of FIG. 2A.

The processing chamber 400 may also include a pedestal 435 that may correspond with pedestal 265 of FIG. 2A. The pedestal 435 may include a stem 445 coupled with a platen 440. The platen may include an upper surface 475 and a lower surface 470. A substrate may be positioned or seated on the upper surface 475 of the platen 440. The lower surface 470 of the platen 440 may define a portion of a lower region 480 of the processing chamber 400. Inert gases may be flowed from below the platen 440 during processing for purging. The pedestal 435 may be configured to be vertically translatable to accommodate different processes performed in the processing chamber system 400. When the pedestal 435 is raised to a furthest position wihtin the chamber, such as proximate the showerhead 450, the lower surface 470 of the platen 440 may remain below the upper surface of rim 420 of the pumping liner 415. Stated differently, a plane extending horizontally from the lower surface 470 of the platen 440 may remain below or may at least intersect a location below the upper surface of the rim 420 of the pumping liner 415 regardless of the vertical position of the pedestal. Maintaining the lower surface 470 of the platen 440 below the rim 420 of the pumping liner helps choke an alternative flow path, which may facilitate maintaining the flow path 460 of the processing region flowing toward the apertures 430. Gases and byproducts from the processing region 455 may then be limited or prevented from entering the lower region 480 of the processing chamber below the platen 440, or creating turbulence by interfering with the flow path 465 of the inert gas flow from below the platen 440. Providing an additional inert gas flow as noted, may further limit or prevent any byproduct flow into a lower region of the chamber. By preventing the byproducts from the processing region 455 from entering the lower region 480, buildup on the lower surface 470 of the platen 440 is mitigated. This may improve the thermal uniformity of the substrate during processing, and may reduce chamber downtime for cleaning.

In use, a substrate placed on the upper surface 475 of the platen 440 may be exposed to plasma entering the processing region 455 through the showerhead 450. Byproducts and gases from the processing region 455 may be exhausted along flow path 460 which is streamlined to more readily access apertures 430 along a natural flow path with a controlled and curved directional change from across the substrate and extending through into the pumping plenum via the void area created by the inner annular surface 410 of spacer 405. The flow path may not include any sharper angled directional changes, such as a substantially ninety-degree turn into the sidewall of the pumping liner. The inert gases entering the lower region 480 may be exhausted from the lower region 480 along flow path 465, which combines with flow path 460 just above rim 420 to exit the processing chamber 400 via apertures 430 and plenum 425.

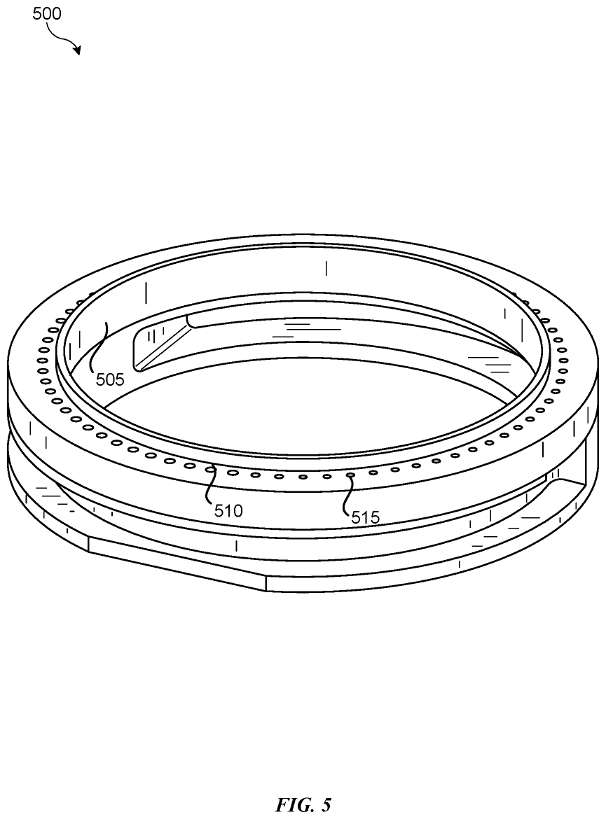

FIG. 5 illustrates a pumping liner 500 for use in a semiconductor processing chamber. The pumping liner 500 may correspond to pumping liner 415 of FIG. 4, and may include any of the features, components or aspects of the pumping liner as described above. The pumping liner may be annular and include an inner annular surface 505. Rim 510 may extend vertically from the inner annular surface 505 and all along the inner annular surface 505 of the pumping liner 415. The rim 510 may correspond to rim 420 of FIG. 4, and may create a ridge extending beyond the bottom surface of the pedestal in a raised operational position. The pumping liner 500 may define apertures 515 that may correspond to apertures 430 of FIG. 4. The apertures 515 may provide fluid access to a plenum defined within pumping liner 500 as illustrated above. The apertures 515 may be disposed along a surface extending orthogonally to the inner annular surface 505. The apertures 515 may be disposed equidistantly or at any equal or unequal interval about the pumping liner. Additionally, the apertures may be equally-sized, or may be sized along a gradient to further control flow through the plenum to improve uniformity. For example, the system foreline may couple with a single location about the chamber, which may affect effluent flow at that location relative to a location further from the foreline coupling. Accordingly, for example, apertures through the pumping liner at a location further from the foreline connection may be formed larger than apertures proximate the foreline connection, which may equalize flow conductance from the processing region into the pumping liner in some embodiments. Any other variations in apertures location and sizing may similarly be produced and are also encompassed by the present technology.

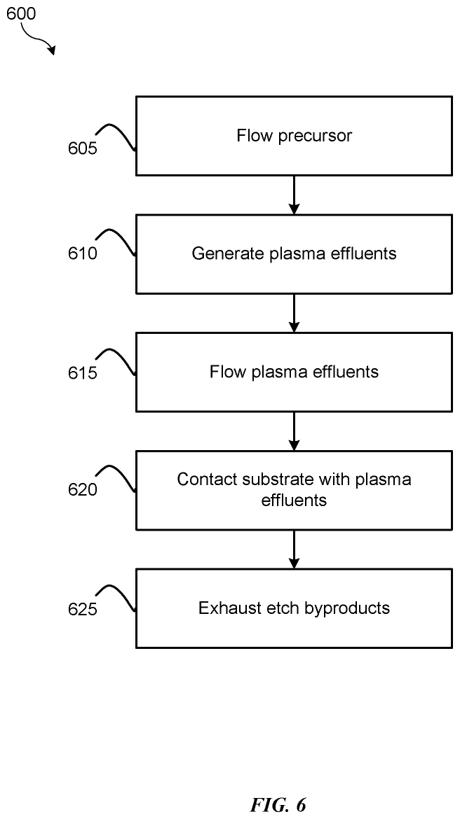

The configurations and systems described above may be utilized during processing operations to improve flow of gases and processing byproducts across the substrate, and mitigate or limit byproduct re-deposition on chamber components or access into the region below the platen of the pedestal. FIG. 6 shows selected operations in an exemplary processing method 600 according to some embodiments. Method 600 may include one or more operations prior to the initiation of the method, including front end processing, deposition, gate formation, etching, polishing, cleaning, or any other operations that may be performed prior to the described operations. The method may include a number of optional operations, which may or may not be specifically associated with some embodiments of methods according to the present technology. For example, many of the operations are described in order to provide a broader scope of the processes being performed, but are not critical to the technology, or may be performed by alternative methodology as will be discussed further below.

Prior to the first operation of the method 600, a substrate may be processed in one or more ways before being placed within a processing region of a chamber in which method 600 may be performed. For example, after a mask layer is formed on a substrate, an etching operation may be performed to selectively etch one or more materials relative to the mask. The layers of material may include any substrate materials or semiconductor structures. Some or all of these operations may be performed in chambers or system tools as described elsewhere in the present disclosure, or may be performed in different chambers on the same system tool, which may include the chamber in which the operations of method 600 are performed.

The method 600 may include flowing one or more etchant precursors into a remote plasma region of a semiconductor processing chamber at operation 605. An exemplary chamber may include any of the components or configurations described elsewhere in this disclosure, which may include a remote plasma region defined within the processing chamber or in a separately unit fluidly coupled with the chamber, and separated from a processing region in which a substrate may be housed. Exemplary precursors may include a fluorine-containing precursor and a hydrogen-containing precursor along with one or more carrier gases, although other precursors used in etching may similarly be used according to embodiments of the present technology. A plasma may be generated within the remote plasma region at operation 610, which may generate plasma effluents of the etchant precursors. The plasma effluents may be flowed to a processing region of the semiconductor processing chamber at operation 615. The plasma effluents may be flowed through a showerhead to access a processing region of the chamber in which a substrate may be housed.

The plasma effluents may contact the mask material, or any other material to be etched, and may remove the material from the substrate at operation 620. The etching operation may produce a number of byproducts, which may include boron-containing byproducts in some embodiments of the present technology. The byproducts from the etching operation may be exhausted from the processing region at operation 625. The byproducts may be exhausted through a pumping liner such as pumping liner 415 of FIG. 4 or pumping liner 500 of FIG. 5. A first surface of the pumping liner facing the showerhead may include apertures, e.g., apertures 515 of FIG. 5 or apertures 430 of FIG. 4, through which the byproducts are exhausted. As previously described, a rim on the inner annular surface of the pumping liner may further encourage the flow path of the exhaust byproducts and gases through the apertures, and prevent flow below the pedestal platen. A spacer as previously described may also be included between the pumping liner and showerhead, which may define an arcuate profile along an interior surface that further encourages the flow path of the exhaust byproducts and gases through the apertures.

In some embodiments, inert gases may be flowed into the lower region of the processing chamber below the pedestal as previously described. The inert gases may be exhausted from the chamber through the apertures of the plenum, thereby further limiting flow of the byproducts into the lower region of the processing chamber. The chamber may be configured so that the rim of the pumping liner remains above the plane of the lower surface of the platen, further limiting flow of the byproducts into the lower region of the processing chamber in view of the flow path of the inert gases from below the pedestal flowing up between the pumping liner and the platen. Consequently, uniformity of material removal from the substrate may be improved due to a number of factors. For example, fall on particles re-deposited on chamber surfaces may be limited, and buildup of byproducts on the lower surface of the platen may be limited or prevented, which may improve temperature uniformity on the substrate, further improving process uniformity across the substrate.

In the preceding description, for the purposes of explanation, numerous details have been set forth in order to provide an understanding of various embodiments of the present technology. It will be apparent to one skilled in the art, however, that certain embodiments may be practiced without some of these details or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a,” “an,” and “the” include plural references unless the context clearly dictates otherwise. Thus, for example, reference to “an aperture” includes a plurality of such apertures, and reference to “the component” includes reference to one or more components and equivalents thereof known to those skilled in the art, and so forth.

Also, the words “comprise(s),” “comprising,” “contain(s),” “containing,” “include(s),” and “including,” when used in this specification and in the following claims, are intended to specify the presence of stated features, integers, components, or operations, but they do not preclude the presence or addition of one or more other features, integers, components, operations, acts, or groups.

1. A semiconductor processing chamber, comprising:
a showerhead;
a pedestal configured to support a semiconductor substrate, wherein the showerhead and pedestal at least partially define a processing region within the semiconductor processing chamber;
a spacer characterized by a first surface in contact with the showerhead and a second surface opposite the first surface; and
a pumping liner characterized by a first surface in contact with the spacer, and a second surface opposite the first surface, wherein the pumping liner defines a plurality of apertures within the first surface of the pumping liner.

2. The semiconductor processing chamber of claim 1, wherein the spacer comprises an annulus, and wherein an inner annular sidewall of the spacer extending between the first surface of the spacer and the second surface of the spacer at least partially defines the processing region.

3. The semiconductor processing chamber of claim 2, wherein the inner annular sidewall of the spacer is at least partially characterized by an arcuate profile extending away from the processing region in a direction towards the second surface of the spacer.

4. The semiconductor processing chamber of claim 3, wherein the inner annular sidewall of the spacer at the second surface of the spacer is positioned radially outward of the plurality of apertures within the first surface of the pumping liner.

5. The semiconductor processing chamber of claim 1, wherein the second surface of the spacer is seated on the pumping liner.

6. The semiconductor processing chamber of claim 1, wherein the pumping liner comprises an annulus characterized by an inner annular sidewall and an outer annular sidewall, and wherein the pumping liner defines a plenum between the inner annular sidewall and the outer annular sidewall.

7. The semiconductor processing chamber of claim 6, wherein the plurality of apertures provide fluid access to the plenum from the first surface of the pumping liner.

8. The semiconductor processing chamber of claim 6, wherein the inner annular sidewall of the pumping liner extends vertically to define a rim protruding from the first surface of the pumping liner at the inner annular sidewall.

9. The semiconductor processing chamber of claim 8, wherein the pedestal is vertically translatable within the processing region of the semiconductor processing chamber, and wherein the pedestal comprises a platen and a stem extending from a backside of the platen.

10. The semiconductor processing chamber of claim 9, wherein, when the pedestal is in a raised operational position proximate the showerhead, a plane across the backside of the platen is maintained below an upper surface of the rim protruding from the first surface of the pumping liner.

11. A semiconductor processing chamber pumping liner, comprising:
an annular member characterized by:
a first surface, wherein a plurality of apertures are defined through the first surface of the annular member,
a second surface opposite the first surface,
an inner annular sidewall, and
an outer annular sidewall.

12. The semiconductor processing chamber pumping liner of claim 11, wherein the second surface defines a plenum about the annular member extending towards the first surface between the inner annular sidewall and the outer annular sidewall.

13. The semiconductor processing chamber pumping liner of claim 12, wherein the plurality of apertures provide fluid access to the plenum through the first surface of the annular member.

14. The semiconductor processing chamber pumping liner of claim 11, wherein the inner annular sidewall of the annular member extends vertically to define a rim protruding from the first surface at the inner annular sidewall.

15. The semiconductor processing chamber pumping liner of claim 14, wherein the rim extends continuously about the inner annular sidewall.

16. A method of semiconductor processing, the method comprising:
flowing an etchant precursor into a remote plasma region of a semiconductor processing chamber;
generating plasma effluents of the etchant precursor within the remote plasma region of the semiconductor processing chamber;
flowing the plasma effluents of the etchant precursor through a showerhead into a processing region of the semiconductor processing chamber;
contacting a substrate with the plasma effluents, wherein the substrate is seated on a pedestal; and
exhausting etch byproducts from the processing region through a pumping liner characterized by a first surface facing the showerhead and a second surface opposite the first surface, wherein the pumping liner defines a plurality of apertures within the first surface of the pumping liner.

17. The method of semiconductor processing of claim 16, wherein the semiconductor processing chamber further comprises a spacer characterized by a first surface in contact with the showerhead and a second surface opposite the first surface and in contact with the pumping liner, wherein the spacer comprises an annulus, and wherein an inner annular sidewall of the spacer extending between the first surface of the spacer and the second surface of the spacer at least partially defines the processing region.

18. The method of semiconductor processing of claim 17, wherein the inner annular sidewall of the spacer is at least partially characterized by an arcuate profile extending away from the processing region in a direction towards the second surface of the spacer.

19. The method of semiconductor processing of claim 18, wherein the inner annular sidewall of the spacer at the second surface of the spacer is positioned radially outward of the plurality of apertures within the first surface of the pumping liner.

20. The method of semiconductor processing of claim 16, wherein the pumping liner is further characterized by an inner annular sidewall, and wherein the inner annular sidewall extends vertically to define a rim protruding from the first surface of the pumping liner at the inner annular sidewall.
